(19) United States
(12) Patent Application Publication
(10) Pub. No.: US 2023/0143139 A1
(43) Pub. Date: May 11, 2023

(54) STACK PACKAGES INCLUDING BONDING WIRE INTERCONNECTIONS

(71) Applicant: SK hynix Inc., Icheon-si Gyeonggi-do (KR)

(72) Inventor: Ria YOO, Icheon-si Gyeonggi-do (KR)

(73) Assignee: SK hynix Inc., Icheon-si Gyeonggi-do (KR)

(21) Appl. No.: 17/730,587

(22) Filed: Apr. 27, 2022

(30) Foreign Application Priority Data
Nov. 8, 2021 (KR) 10-2021-0152628

(51) Int. Cl. H01L 25/065

(52) U.S. Cl. CPC H01L 25/0657; H01L 2225/0651; H01L 2225/06562

(57) ABSTRACT

There is provided a stack package. The stack package includes a packaging substrate and a chip stack disposed over the packaging substrate. The chip stack includes a second semiconductor chip that is stacked over a first semiconductor chip. The stack package further includes a first bonding wire connecting the first semiconductor chip to a first position of the packaging substrate and a second bonding wire connecting the second semiconductor chip to a second position of the packaging substrate. The second position of the packaging substrate may be closer to the chip stack than the first position of the packaging substrate.

### CROSS-REFERENCE TO RELATED APPLICATIONS

The present application claims priority under 35 U.S.C 119(a) to Korean Application No. 10-2021-0152628, filed on Nov. 8, 2021, which is incorporated herein by reference in its entirety.

### BACKGROUND

### 1. Technical Field

The present disclosure generally relates to a semiconductor packaging technology, and more particularly, to stack packages including bonding wire interconnections.

### 2. Related Art

Recently, as electronic products are miniaturized and have improved in performance and demand for portable mobile products has increased, semiconductor package products having a large capacity, low power consumption, or high-speed operation are required. Attempts are being made to embed a larger number of semiconductor chips in a semiconductor package. Various types of semiconductor package structures in which a plurality of semiconductor chips are stacked on each other have been proposed. The bonding wires may signally and electrically connect the stacked semiconductor chips to a packaging substrate. The length of the bonding wires may vary according to the height at which the semiconductor chips are located.

### SUMMARY

An embodiment of the present disclosure may provide a stack package including a packaging substrate, a first bond finger disposed over the packaging substrate, wherein the first bond finger includes a first portion and a second portion, a chip stack disposed over the packaging substrate, wherein the chip stack includes a second semiconductor chip including a second chip pad that is stacked over a first semiconductor chip including a first chip pad, a first bonding wire connecting the first chip pad to the first portion of the first bond finger, and a second bonding wire connecting the second chip pad to the second portion of the first bond finger. The second portion of the first bond finger may be closer to the chip stack than the first portion of the first bond finger.

Another embodiment of the present disclosure may provide a stack package including a packaging substrate, a chip stack disposed over the packaging substrate, the chip stack including a second semiconductor chip including a second chip pad that is stacked over a first semiconductor chip including a first chip pad, a first bonding wire connecting the first semiconductor chip to a first position of the packaging substrate, and a second bonding wire connecting the second semiconductor chip to a second position of the packaging substrate. The second position of the packaging substrate may be closer to the chip stack than the first position of the packaging substrate.

### BRIEF DESCRIPTION OF THE DRAWINGS

FIG. 1 is a schematic cross-sectional view illustrating a stack package according to an embodiment of the present disclosure.

FIG. 2 is a schematic plan view illustrating an interconnection structure of first and second bonding wires of the stack package of FIG. 1.

FIGS. 3 and 4 are schematic plan views illustrating stack packages according to other embodiments of the present disclosure.

FIG. 5 is a schematic cross-sectional view illustrating a bonding wire of the stack package of FIG. 1.

FIG. 6 is a schematic cross-sectional view illustrating a stack package according to another embodiment of the present disclosure.

FIG. 7 is a block diagram illustrating an electronic system employing a memory card including a package according to an embodiment of the present disclosure.

FIG. 8 is a block diagram illustrating an electronic system including a package according to an embodiment of the present disclosure.

### DETAILED DESCRIPTION

The terms used herein may correspond to words selected in consideration of their functions in presented embodiments, and the meanings of the terms may be construed to be different according to ordinary skill in the art to which the embodiments belong. If defined in detail, the terms may be construed according to the definitions. Unless otherwise defined, the terms (including technical and scientific terms) used herein have the same meaning as commonly understood by one of ordinary skill in the art to which the embodiments belong.

It will be understood that although the terms “first” and “second,” “side,” “top,” and “bottom or lower” may be used herein to describe various devices, these devices should not be limited by these terms. These terms are only used to distinguish one device from another device, but not used to indicate a particular sequence or number of devices.

The semiconductor device may include a semiconductor substrate or a structure in which a plurality of semiconductor substrates are stacked. The semiconductor device may refer to a semiconductor package structure in which a structure in which semiconductor substrates are stacked is packaged. The semiconductor substrate may refer to a semiconductor wafer, a semiconductor the, or a semiconductor chip in which electronic components and devices are integrated. The semiconductor chip may refer to a memory chip in which memory integrated circuits, such as dynamic random access memory (DRAM) circuits, static random access memory (SRAM) circuits, NAND-type flash memory circuits, NOR-type flash memory circuits, magnetic random access memory (MRAM) circuits, resistive random access memory (ReRAM) circuits, ferroelectric random access memory (FeRAM) circuits, or phase change random access memory (PcRAM) are integrated, logic dies or ASIC chips in which logic circuits are integrated in a semiconductor substrate, or processors, such as application processors (Aps), graphic processing units (GPUs), central processing units (CPUs) or system-on-chips (SoCs). The semiconductor device may be employed in information communication systems, such as mobile phones, electronic systems associated with biotechnology or health care, or wearable electronic systems. The semiconductor device may be applicable to internet of things (IoT).

Same reference numerals refer to same devices throughout the specification. Even though a reference numeral might not be mentioned or described with reference to a drawing, the reference numeral may be mentioned or described with reference to another drawing. In addition, even though a reference numeral might not be shown in a drawing, it may be shown in another drawing.

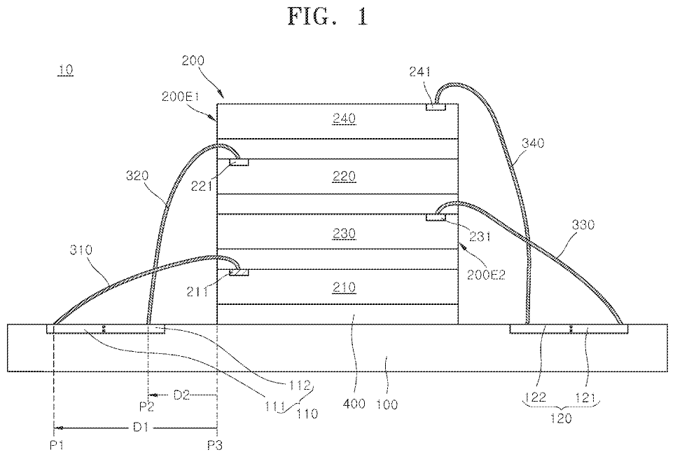

FIG. 1 is a schematic cross-sectional view illustrating a stack package 10 according to an embodiment of the present disclosure.

Referring to FIG. 1, the stack package 10 may include a packaging substrate 100, a chip stack 200, and bonding wires 310, 320, 330, and 340. The chip stack 200 may have a structure in which a plurality of semiconductor chips 210, 220, 230, and 240 are substantially vertically stacked. The bonding wires 310, 320, 330, and 340 may electrically and signally connect the semiconductor chips 210, 220, 230, and 240 to the packaging substrate 100. Although not illustrated, the stack package 10 may further include an encapsulant that covers and protects the chip stack 200.

The packaging substrate 100 may include interconnection components that electrically connect the semiconductor chips 210, 220, 230, and 240 of the chip stack 200 to an external device or external module, or external components. In an example, the packaging substrate 100 may be configured in the form of a printed circuit board (PCB). In an example, the packaging substrate 100 may be configured in an interconnection structure including conductive patterns that are disposed in a dielectric layer. The conductive patterns may indicate a redistribution layer (RDL).

The chip stack 200 may be disposed on the packaging substrate 100. The semiconductor chips 210, 220, 230, and 240 may be sequentially stacked in a direction that is substantially perpendicular to the packaging substrate 100 to configure the chip stack 200. Adhesion layers 400 may be disposed between the chip stack 200 and the packaging substrate 100 or between the semiconductor chips 210, 220, 230, and 240. The adhesion layer 400 may adhere the semiconductor chips 210, 220, 230, and 240 to each other or adhere the chip stack 200 to the packaging substrate 100. Each of the semiconductor chips 210, 220, 230, and 240 may include a semiconductor device in which integrated circuits are integrated. The semiconductor device may include a memory device, such as a dynamic random-access memory (DRAM) device or a NAND flash memory device.

The first semiconductor chip 210 may be disposed over the packaging substrate 100, and the second semiconductor chip 220 may be stacked over the first semiconductor chip 210. The first semiconductor chip 210 may include first chip pads 211 that are disposed to be adjacent to a first side 200E1 of the chip stack 200. The plurality of first chip pads 211 may be arranged, side by side, in a direction in which the first side 200E1 of the chip stack 200 extends. The second semiconductor chip 220 may include second chip pads 221 that are disposed to be adjacent to the first side 200E1 of the chip stack 200. The plurality of second chip pads 221 may be arranged, side by side, in a direction in which the first side 200E1 of the chip stack 200 extends.

The third semiconductor chip 230 may be disposed between the first semiconductor chip 210 and the second semiconductor chip 220. The third semiconductor chip 230 may include third chip pads 231 that are disposed to be adjacent to a second side 200E2 the is opposite to the first side 200E1 of the chip stack 200. The fourth semiconductor chip 240 may be stacked over the second semiconductor chip 220. The fourth semiconductor chip 240 may include fourth chip pads 241 that are disposed to be adjacent to the second side 200E2 of the chip stack 200.

The packaging substrate 100 may include bond fingers 110 and 120 to which bonding wires 210, 320, 330, and 340 are connected as conductive patterns. The first bond fingers 110 and the second bond fingers 120 may be respectively disposed on opposite sides of the chip stack 200 on the packaging substrate 100. The plurality of first bond fingers 110 may be arranged to be adjacent to the first side 200E1 of the chip stack 200 extends. The plurality of second bond fingers 120 may be arranged to be adjacent to the second side 200E2 that is the opposite side to the first side 200E1 of the chip stack 200.

Each of the first bond fingers 110 may be formed in a conductive pattern including a first portion 111 and a second portion 112. The first portion 111 of the first bond finger 110 may be a portion of the first bond finger 110 to which the first bonding wire 310 is connected. The second portion 112 of the first bond finger 110 may be another portion of the first bond finger 110 to which the second bonding wire 320 is connected. The second portion 112 of the first bond finger 110 may be a portion of the first bond finger 110 that is positioned closer to the chip stack 200 than the first portion 111.

The second bond fingers 120 may be disposed on the opposite side of the first bond finger 110 to have substantially the same pattern shape as the first bond finger 110. Each of the second bond fingers 120 may be formed as a conductive pattern including a third portion 121 and a fourth portion 122. The third portion 121 of the second bond finger 120 may be a portion of the second bond finger 120 to which the third bonding wire 330 is connected. The fourth portion 122 of the second bond finger 120 may be another portion of the second bond finger 120 to which the fourth bonding wire 340 is connected.

The first bonding wire 310 may connect the first chip pad 211 of the first semiconductor chip 210 to the first portion 111 of the first bond finger 110. The second bonding wire 320 may connect the second chip pad 221 of the second semiconductor chip 220 that is disposed at an upper position that is higher than the first semiconductor chip 210 to the second portion 112 of the first bond finger 110. The first bonding wire 310 may be connected to the first portion 112 of the first bond finger 110 at a position P1, and the second bonding wire 320 may be connected to the second portion 112 of the first bond finger 110 at a position P2.

The position P2 may be a position that is spaced apart from a position P3 of the first side 200E1 of the chip stack 200 by a second separation distance D2, which may indicate a position at which the chip stack 200 is located. The position P1 may be a position that is spaced apart from the position P3 by a first separation distance D1. The second separation distance D2 may have a smaller value than the first separation distance D1. As such, the second bonding wire 320 may be connected or bonded to the packaging substrate 100 or the first bond finger 110 at a position that is closer to the chip stack 200 than the first bonding wire 310. Accordingly, a length difference between the second bonding wire 320 and the first bonding wire 310 may be reduced.

The length difference between the second bonding wire 320 and the first bonding wire 310 may be reduced compared to a case in which the second bonding wire 320 and the first bonding wire 310 are connected at substantially the same position on the packaging substrate 100. The length difference between the second bonding wire 320 and the first bonding wire 310 may be reduced compared to a case in which the second bonding wire 320 is connected at another position of the packaging substrate 100 that is further away from the chip stack 200 than the position at which the first bonding wire 310 is connected to the packaging substrate 100. The length difference between the second bonding wire 320 and the first bonding wire 310 may act as a factor that impairs signal integrity (SI) characteristics of data signals that are transmitted to the first semiconductor chip 210 and the second semiconductor chip 220. The length difference between the second bonding wire 320 and the first bonding wire 310 may be reduced, so that the signal integrity (SI) characteristic of the stack package 10 may be improved.

When the eye diagrams are measured for a first embodiment in which the lengths of the first bonding wire 310 and the second bonding wire 320 are 2500 micrometers (μm) and 500 μm, respectively, a second embodiment in which the lengths of the first bonding wire 310 and the second bonding wire 320 are 2000 μm and 1000 μm, respectively, and a third embodiment in which the lengths of the first bonding wire 310 and the second bonding wire 320 are 1500 μm and 1500 μm, respectively, it can be seen that the eye height is increased in the order of the first, second, and third embodiments. That is, it can be seen that as the length difference between the first bonding wire 310 and the second bonding wire 320 is reduced, the eye height of the eye diagram that reflects the signal quality is increased. Since increasing the eye height of the eye diagram means that the signal integrity (SI) is improved, as the length difference between the first and second bonding wires 310 and 320 is reduced, the signal integrity SI may be improved and signal reflection may be reduced.

The first chip pad 211 of the first semiconductor chip 210 and the second chip pad 221 of the second semiconductor chip 220 may be commonly connected to the first bond finger 110. When data is transmitted to the first semiconductor chip 210 through the first bond finger 110, a signal that is reflected from the second semiconductor chip 220 may be generated. When data is transmitted to the second semiconductor chip 220 through the first bond finger 110, a signal that is reflected from the first semiconductor chip 210 may be generated. The timing difference between these two reflection signals may increase in proportion to the length difference between the second bonding wire 320 and the first bonding wire 310 and may act as a factor that impairs the signal integrity (SI) characteristic of the stack package 10. Since the length difference between the second bonding wire 320 and the first bonding wire 310 may be reduced, the timing difference between the reflection signals may be reduced, and the signal integrity (SI) characteristic of the stack package 10 may be improved.

The third bonding wire 330 may connect the third chip pad 231 of the third semiconductor chip 230 to the third portion 121 of the second bond finger 120. The fourth bonding wire 340 may connect the fourth chip pad 241 of the fourth semiconductor chip 240 disposed at a higher position than the third semiconductor chip 230 to the fourth portion 122 of the second bond finger 120. The fourth bonding wire 340 may be connected to or bonded to the packaging substrate 100 or the second bond finger 120 at a position closer to the chip stack 200 than the third bonding wire 330. Accordingly, a length difference between the fourth bonding wire 340 and the third bonding wire 330 may be reduced.

As the third semiconductor chip 230 is stacked between the first semiconductor chip 210 and the second semiconductor chip 220, a length difference between the third bonding wire 330 and the first bonding wire 310 may be reduced compared to a case in which the third semiconductor chip 230 is disposed on the second semiconductor chip 220. Accordingly, the signal integrity of the stack package 10 may be improved.

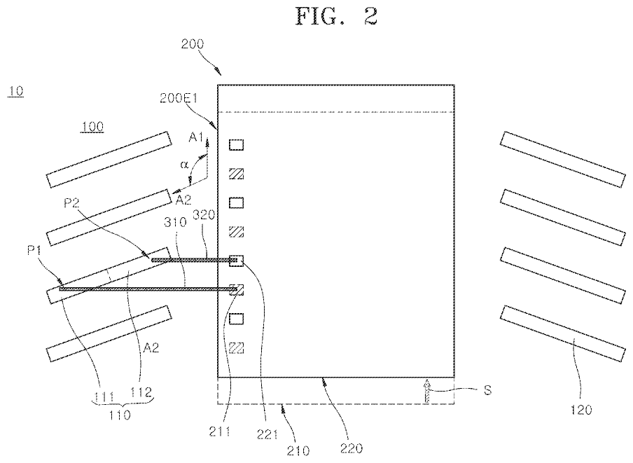

FIG. 2 is a schematic plan view illustrating an interconnection structure of the first and second bonding wires 310 and 320 of the stack package 10 of FIG. 1.

Referring to FIG. 2 along with FIG. 1, the first bond finger 110 may have a shape of a conductive pattern that extends in a diagonal direction A2 with respect to the first side 200E1 of the chip stack 200. The first bond finger 110 may be configured in a conductive pattern elongated in the diagonal direction A2 intersecting at a predetermined angle α with respect to the extension direction A1 of the first side 200E1 of the chip stack 200. The diagonal direction A2 in which the first bond fingers 110 extend may intersect with respect to the extension direction A1 of the first side 200E1 of the chip stack 200 at an angle α greater than approximately 90 degrees) (°) and less than 180°. The second bond fingers 120 may be disposed on the portion of the packaging substrate 100 on the opposite side of the chip stack 200 in relation to the first bond fingers 110. The second bond finger 120 may extend in the intersecting diagonal direction A2 with the first side 200E1 of the chip stack 200 at a predetermined angle, for example, greater than 180 degrees (°) and less than 270°.

As the first bond fingers 110 extend in the diagonal direction A2 with respect to the first side 200E1 of the chip stack 200, the position P1 at which the first bonding wire 310 is bonded to the first portion 111 of the first bond finger 110 may be spaced apart from the position P2 at which the second bonding wire 320 is bonded to the second portion 121 of the first bond finger 110 by a predetermined spacing along the direction A1 in which the first side 200E1 of the chip stack 200 extends. Accordingly, the trajectories in which the first bonding wire 310 and the second bonding wire 320 extend may be spaced apart from each other. When viewed from the side, FIG. 1 shows that the trajectories of the first bonding wire 310 and the second bonding wire 320 intersect each other, but the first bonding wire 310 and the second bonding wire 320 may be spaced apart from each other along the direction A1 in which the first side 200E1 of the chip stack 200 extends, in a plan view, as shown in FIG. 2. Accordingly, while preventing the first bonding wire 310 and the second bonding wire 320 from being electrically shorted by contacting each other, the first bonding wire 310 may extend to the position P1 of the packaging substrate 100 farther from the chip stack 200 than the second bonding wire 320,

The second semiconductor chip 220 of the chip stack 200 may be offset by a certain distance S with respect to the first semiconductor chip 210 and may be offset-stacked over the first semiconductor chip 210. The second semiconductor chip 220 may move by the distance S along a direction in which the first side 200E1 of the chip stack 200 extends and may be offset stacked over the first semiconductor chip 210. Accordingly, the second chip pad 221 of the second semiconductor chip 220 may be located at a position that is away from the first chip pad 211 of the first semiconductor chip 210 in the direction A1 in which the first side 200E1 of the chip stack 200 extends. The second semiconductor chip 220 may be offset-stacked over the first semiconductor chip 210 such that the second chip pad 221 of the second semiconductor chip 220 is positioned while overlapping with the position between the first chip pad 211 of the first semiconductor chip 210 and other adjacent first chip pads 211.

The second chip pad 221 may be spaced apart from the first chip pad 211 in the direction A1 in which the first side 200E1 of the chip stack 200 extends so that the first bonding wire 310 and the second bonding wire 320 may be further spaced apart from each other along the direction A1 in which the first side 200E1 of the chip stack 200 extends. Accordingly, it is possible to more effectively reduce or substantially prevent the first bonding wire 310 and the second bonding wire 320 from being in contact with each other and being electrically shorted.

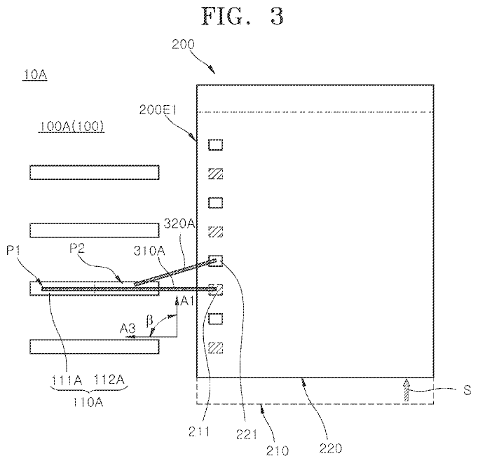

FIG. 3 is a schematic plan view illustrating a stack package 10A according to another embodiment of the present disclosure.

Referring to FIG. 3, the stack package 10A may include first bonding fingers 110A that extend in a direction A3 substantially perpendicular to a first side 200E1 of a chip stack 200. The vertical direction A3 may be a direction that extends on a surface of the packaging substrate 100A, intersecting a direction A1 in which the first side 200E1 of the chip stack 200 extends at an angle β that is substantially 90 degrees (°). Since the first bond fingers 110A extend in the direction A3 substantially perpendicular to the first side 200E1 of the chip stack 200, a position P1 at which the first bonding wire 310 is bonded to a first portion 111A of the first bond finger 110 might not be substantially spaced apart from a position P2 at which a second bonding wire 320 is bonded to a second portion 112A of the first bond finger 110A in the direction A1 in which the first side 200E1 of the chip stack 200 extends.

The second semiconductor chip 220 of the chip stack 200 may be offset by a certain distance S with respect to the first semiconductor chip 210 so that a second chip pad 221 of the second semiconductor chip 220 may be positioned at a position that is away from a first chip pad 211 of the first semiconductor chip 210 along the direction A1 in which the first side 200E1 of the chip stack 200 extends. Since the second chip pad 221 is spaced apart from the first chip pad 211 in the direction A1 in which the first side 200E1 of the chip stack 200 extends, the first bonding wire 310 and the second bonding wire 320 may be spaced apart from each other along the direction A1 in which the first side 200E1 of the chip stack 200 extends. Accordingly, it is possible to more effectively reduce or substantially prevent the first bonding wire 310 and the second bonding wire 320 from being in contact with each other and being electrically shorted.

FIG. 4 is a schematic plan view illustrating a stack package 103 according to another embodiment of the present disclosure.

Referring to FIG. 4, a second semiconductor chip 220 of a chip stack 200 may be stacked over a first semiconductor chip 210 to be fully overlapped with the first semiconductor chip 210. A second chip pad 221 of the second semiconductor chip 220 may be positioned at a position that is overlapped with a first chip pad 211 of the first semiconductor chip 210. First bond fingers 110 may extend in a diagonal direction A2 with respect to a first side 200E1 of the chip stack 200. Accordingly, a position P1 at which the first bonding wire 310B is bonded to the first portion 111 of the first bond finger 110 may be spaced apart from a position P2 at which the second bonding wire 320B is bonded to the second portion 112 of the first bond finger 110 by a certain distance along a direction A1 in which the first side 200E1 of the chip stack 200 extends. Accordingly, it is possible to more effectively reduce or substantially prevent the first bonding wire 310 and the second bonding wire 320 from being in contact with each other and being electrically shorted.

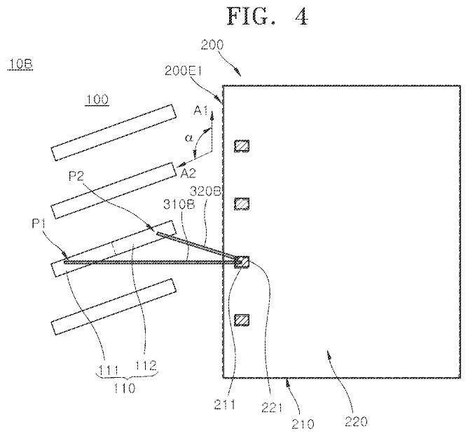

FIG. 5 is a schematic cross-sectional view illustrating a bonding wire 300 of the stack package 10 of FIG. 1.

Referring to FIGS. 1 and 5, an insulation coating layer 302 may be coated on the first, second, third, and fourth bonding wires 310, 320, 330, and 340 of the stack package 10. A wire structure 300 illustrated in FIG. 5 may show a cross-sectional shape in which the insulation coating layer 302 is coated on a wire body 301. The wire body 301 may indicate the first, second, third, and fourth bonding wires 310, 320, 330, and 340 of the stack package 10 of FIG. 1. As illustrated in FIG. 1, after forming the first bonding wire 310, the first bonding wire 310 may be covered by coating with an insulating resin or spraying an insulating resin. Thereafter, the insulation coating layer 302 may be formed by curing the coated insulating resin. By irradiating ultraviolet (UV) light to the coated insulating resin, the insulating resin may be cured. After coating the first bonding wire 310, the second bonding wire 320 may be bonded, and then the second bonding wire 320 may be coated.

In this way, since the first bonding wire 310 and the second bonding wire 320 may be insulated by being coated with the insulation coating layer 302, it is possible to effectively reduce or substantially prevent an electrical short circuit, even when the first bonding wire 310 and the second bonding wire 320 contact each other.

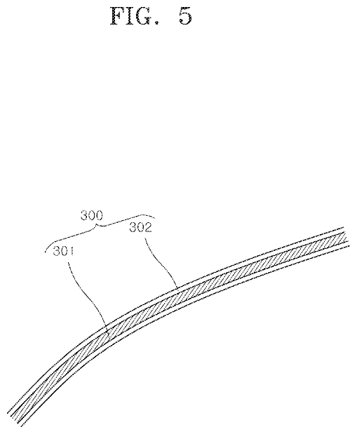

FIG. 6 is a schematic cross-sectional view illustrating a stack package 11 according to another embodiment of the present disclosure. In FIG. 6, elements indicated by the same reference numerals as in FIG. 1 may be designated as substantially identical elements.

Referring to FIG. 6, the stack package 11 may include a packaging substrate 100, a chip stack 201, and first, second, third, and fourth bonding wires 310-1, 320-1, 330-1, and 340-1. The chip stack 201 may be configured in a structure in which first, second, third, and fourth semiconductor chips 210-1, 220-1, 230-1, and 240-1 are sequentially stacked. The second semiconductor chip 220-1 may be stacked over the first semiconductor chip 210-1, and the third and fourth semiconductor chips 230-1 and 2401-1 may be sequentially stacked over the second semiconductor chip 220-1.

The first bonding wire 310-1 may connect a first chip pad 211-1 of the first semiconductor chip 210-1 to a first portion 111 of a first bond finger 110, and the second bond wire 320-1 may connect a second chip pad 221-1 of the second semiconductor chip 220-1 to a second portion 112 of the first bond finger 110. The third bonding wire 330-1 may connect a third chip pad 231-1 of the third semiconductor chip 230-1 to a first portion 121 of a second bond finger 120, and the fourth bonding wire 340-1 may connect a fourth chip pad 241-1 of the fourth semiconductor chip 240-1 to a second portion 122 of the second bond finger 120.

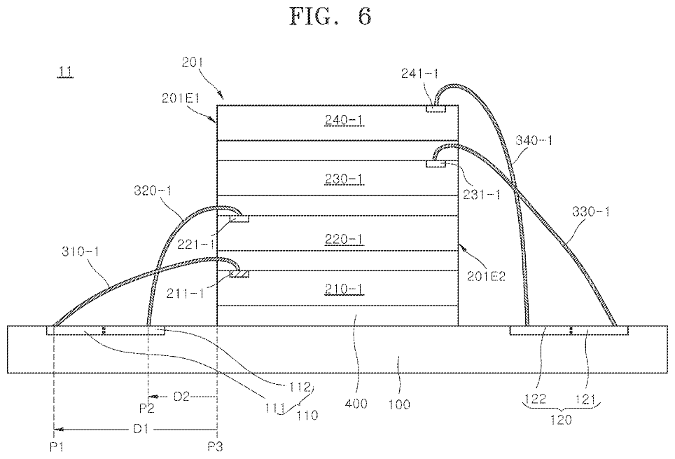

FIG. 7 is a block diagram illustrating an electronic system including a memory card 7800 employing at least one of the semiconductor packages according to the embodiments. The memory card 7800 may include a memory 7810, such as a nonvolatile memory device, and a memory controller 7820. The memory 7810 and the memory controller 7820 may store data or read out the stored data. At least one of the memory 7810 and the memory controller 7820 may include at least one of the semiconductor packages according to the embodiments.

The memory 7810 may include a nonvolatile memory device to which the technology of the embodiments of the present disclosure is applied. The memory controller 7820 may control the memory 7810 such that stored data is read out or data is stored in response to a read/write request from a host 7830.

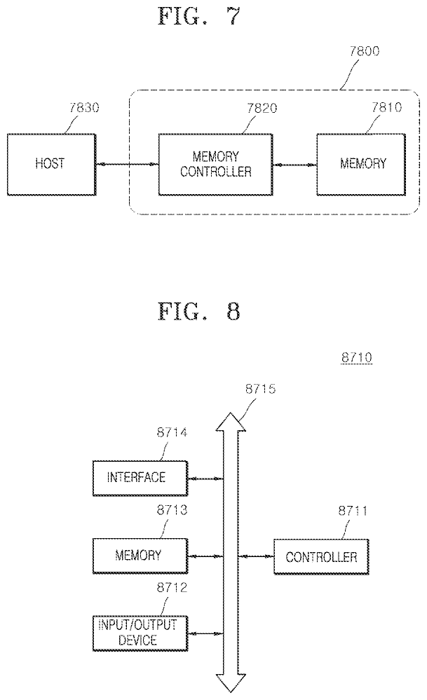

FIG. 8 is a block diagram illustrating an electronic system 8710 including at least one of the semiconductor packages according to the embodiments. The electronic system 8710 may include a controller 8711, an input/output device 8712, and a memory 8713. The controller 8711, the input/output device 8712, and the memory 8713 may be coupled with one another through a bus 8715 providing a path through which data move.

In an embodiment, the controller 8711 may include one or more microprocessor, digital signal processor, microcontroller, and/or logic device capable of performing the same functions as these components. The controller 8711 or the memory 8713 may include at least one of the semiconductor packages according to the embodiments of the present disclosure. The input/output device 8712 may include at least one selected among a keypad, a keyboard, a display device, a touchscreen and so forth. The memory 8713 is a device for storing data. The memory 8713 may store data and/or commands to be executed by the controller 8711, and the like.

The memory 8713 may include a volatile memory device such as a DRAM and/or a nonvolatile memory device such as a flash memory. For example, a flash memory may be mounted to an information processing system such as a mobile terminal or a desktop computer, The flash memory may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

If the electronic system 8710 is an equipment capable of performing wireless communication, the electronic system 8710 may be used in a communication system using a technique of CDMA (code division multiple access), GSM (global system for mobile communications), NADC (north American digital cellular), E-TDMA (enhanced-time division multiple access), WCDMA (wideband code division multiple access), CDMA2000, LTE (long term evolution) or Wibro (wireless broadband Internet).

The inventive concept has been disclosed in conjunction with some embodiments as described above. Those skilled in the art will appreciate that various modifications, additions and substitutions are possible, without departing from the scope and spirit of the present disclosure. Accordingly, the embodiments disclosed in the present specification should be considered from not a restrictive standpoint but an illustrative standpoint. The scope of the inventive concept is not limited to the above descriptions but defined by the accompanying claims, and all of distinctive features in the equivalent scope should be construed as being included in the inventive concept.

What is claimed is:

1. A stack package comprising:
a packaging substrate;
a first bond finger disposed over the packaging substrate, wherein the first bond finger includes a first portion and a second portion;
a chip stack disposed over the packaging substrate, wherein the chip stack includes a second semiconductor chip including a second chip pad that is stacked over a first semiconductor chip including a first chip pad;
a first bonding wire connecting the first chip pad to a first portion of the first bond finger; and
a second bonding wire connecting the second chip pad to a second portion of the first bond finger,
wherein the second portion of the first bond finger is closer to the chip stack than the first portion of the first bond finger.

2. The stack package of claim 1, wherein the first bond finger extends in a diagonal direction with respect to a side of the chip stack.

3. The stack package of claim 1, wherein the second semiconductor chip is offset-stacked over the first semiconductor chip by a certain distance along a direction in which a side of the chip stack closest to the first bond finger extends, in a plan view, so that the second chip pad is farther from the first chip pad.

4. The stack package of claim 1, wherein the second semiconductor chip is offset-stacked over the first semiconductor chip so that, in a plan view, the second chip pad of the second semiconductor chip is positioned between the first chip pad of the first semiconductor chip and another chip pad of the first semiconductor chip adjacent to the first chip pad.

5. The stack package of claim 1, further comprising an insulation coating layer covering the first bonding wire.

6. The stack package of claim 1, wherein the chip stack further includes a third semiconductor chip disposed between the first semiconductor chip and the second semiconductor chip.

7. The stack package of claim 6, wherein the chip stack further includes a fourth semiconductor chip stacked over the second semiconductor chip.

8. The stack package of claim 7, wherein the packaging substrate further includes a second bond finger to which the third semiconductor chip and the fourth semiconductor chip are electrically connected together by addition& bonding wires.

9. The stack package of claim 8, wherein the second bond finger is on an opposite side of the chip stack in relation to the first bond finger.

10. The stack package of claim 1, wherein the chip stack further includes a third semiconductor chip and a fourth semiconductor chip that are sequentially stacked over the second semiconductor chip.

11. A stack package comprising:
a packaging substrate;
a chip stack disposed over the packaging substrate, wherein the chip stack includes a second semiconductor chip including a second chip pad that is stacked over a first semiconductor chip including a first chip pad;
a first bonding wire connecting the first semiconductor chip to a first position of the packaging substrate; and
a second bonding wire connecting the second semiconductor chip to a second position of the packaging substrate, and
wherein the second position of the packaging substrate is closer to the chip stack than the first position of the packaging substrate.

12. The stack package of claim 11, further comprising an insulation coating layer covering the first bonding wire.
